(19) United States
(12) Patent Application Publication
(10) Pub. No.: US 2015/0203975 A1
(43) Pub. Date: Jul. 23, 2015

(54) CONTACT STRIPS FOR ELECTROLYSIS CELLS

(71) Applicants: UHDENNORA, S.P.A., Milan (IT); Thyssenkrupp Industrial Solutions AG, Essen (DE)

(72) Inventors: Dirk Hoormann, Werene an der Lippe (DE); Dmitri Donst, Koln (DE); Frank Funck, Oberhausen (DE); Peter Woltering, Neuenkirchen (DE); Peter Toros, Essen (DE); Philipp Hofmann, Dortmund (DE); Gregor Polcyn, Dortmund (DE)

(73) Assignee: UHDENORA S.P.A., Milan (IT)

(21) Appl. No.: 14/420,835

(22) PCT Filed: Jul. 23, 2013
(86) PCT No.: PCT/EP2013/065522

§ 371 Date: Feb. 10, 2015

(30) Foreign Application Priority Data
Aug. 10, 2012 (DE) 10 2012 015 802.5

(51) Int. Cl. C25B 9/04; C23C 14/16; C23C 14/34

(52) U.S. Cl. CPC C25B 9/045; C23C 14/34; C23C 14/16

(57) ABSTRACT

The invention relates to contact strips for electrolysis cells, the contact strips consisting of a titanium strip which has been coated with a layer of nickel containing 0 to 10 wt.-% vanadium by way of physical vapour deposition.

### FIELD OF THE INVENTION

The invention relates to contact strips, particularly for electrolysis cells (membrane cells), a process for their manufacture and the use of specific metal compositions to obtain conductive compounds.

### PRIOR ART

Electrolysis cells that are connected via contact strips are already known from, for example, WO 1998 15675 A1 (Uhde). Contact strips serve not least to establish electric contact between adjacent cells; however, there are various alternatives on the one hand to manufacture these contact strips and on the other hand to attach them to the cell walls.

A manufacturing process for the production of contact strips of this kind is also described in WO 2001 085388 A1 (Uhde). Here, laser pressure-welding is used to weld contact strips of material of good electric conductivity onto a titanium sheet strip.

DE 2010 023410 A1 (Uhde) describes the manufacture of platinum electrodes for the persulfate electrolysis. In this process a layer of platinum of a thickness of 0.5 to 10 μm is deposited on a substrate metal. Embodiment example 1 describes the manufacture of an electrode in which nickel is applied onto a substrate metal by using the PVD process. However, the person skilled in the art is immediately aware that this must be a mistake as the complete document is exclusively about coating with platinum.

In case sheet strips of dissimilar materials are connected to each other, a known practice is to do so by explosion-bonding. Here, an explosive layer is ignited at high velocity to explosion-bond the coating material to the substrate material so that grid-type metal bonding is achieved between the two materials. However, this method is comparatively sophisticated, especially cost-intensive. In addition, this method produces 20 to 50% material scrap, as the precision of explosion-bonding is too low.

The objective of the invention is to provide contact strips which are as reasonably priced as possible but are nonetheless highly conductive and to develop a highly effective process which allows manufacturing such contact strips of high electric effectiveness on a large scale.

### DESCRIPTION OF THE INVENTION

In a first embodiment, the invention relates to contact strips for electrolysis cells, which consist of a titanium strip coated with a layer of nickel containing 0 to 10 wt.-% vanadium by way of physical vapour deposition.

Surprisingly it has been found that a contact strip provided with such coating that had been applied by physical vapour deposition features high electric effectiveness.

In a preferred embodiment of the invention the nickel contains vanadium of approx. 1 to approx. 8 wt.-% and preferably 7 wt.-%. In this way conductivity and flexibility of the contact strips are further improved. Nickel alloys containing 7 wt.-% vanadium normally serve for semiconductor applications and are commercially available from Umicore AG under the name ‘NiV7’.

Also preferred are contact strips with a layer of nickel or nickel-vanadium of a thickness of approx. 0.5 to approx. 10 μm, preferably of approx. 1 to approx. 8 μm and most preferably of approx. 1 to approx. 5 μm.

Another subject-matter of the invention relates to a process for the manufacture of contact strips for electrolysis cells, according to which a layer of nickel containing vanadium of 0 to 10 wt.-%, preferably approx. 1 to approx. 8 wt.-% and most preferably 7 wt.-% is deposited on a titanium strip by way of physical vapour deposition.

In a preferred but only exemplary embodiment of the invention, the physical vapour deposition is carried out by
(a) loading a vacuum chamber with at least one titanium strip,
(b) closing and evacuating the vacuum chamber,
(c) cleaning the substrate by introducing a gaseous reducing agent into the vacuum chamber,
(d) subsequently removing the gaseous reducing agent,
(e) introducing the nickel or nickel-vanadium into the vacuum chamber and coating the titanium strip with an approx. 0.5 to approx. 10 μm thick layer by vapour deposition, ion plating or cathode sputtering, and
(f) finally, re-flooding the vacuum chamber and removing the coated substrate from the chamber.

Additionally it has proven to be of advantage to perform the process steps (a) to (f) of the physical vapour deposition from one step to the next under vacuum at different pressures, which are set by means of an inert gas.

Most preferably used as a coating process is a vapour deposition method from the group of thermal deposition, electron beam deposition, laser beam deposition, arc deposition and molecular beam epitaxy.

Thermal deposition or thermal evaporation is a high-vacuum-based coating method from the group of PVD processes. In this process all starting material is heated electrically (resistively or inductively) to temperatures close to the boiling point, material vapour migrates to a substrate and condenses there in a layer. It thus constitutes one of the simplest vapour deposition methods in the field of coating technology.

In the extended sense, thermal deposition is understood to be a group of PVD processes in which the starting material is heated in various ways. This group includes, for example, vapour deposition methods using laser beams, electron beams or an arc. Molecular beam epitaxy is another method from this group.

For thermal deposition the starting material is heated to temperatures close to the boiling point. Individual atoms, atom clusters or molecules separate, which means that they evaporate and migrate through the vacuum chamber. On account of the arrangement between evaporation source and substrate, the material vapour gets to as far as the cooler substrate on the opposite side and condenses. A thin layer of the evaporated material deposits on the substrate.

As most of the other PVD processes, thermal deposition is also a high-vacuum process. Typical process pressures are 10⁻⁶ mbar. This is due to various reasons, on the one hand collisions with the gas particles still existing in the vacuum are minimised by the low pressure (in this pressure range the mean free path length is much longer than the distance of the evaporation source to the substrate), on the other hand it is required that the process pressure be below the gas pressure of the material to be evaporated.

A further subject-matter of the invention refers to the use of nickel of a vanadium content of 0 to 10 wt.-%, preferably approx. 1 to approx. 8 wt.-% and most preferably 7 wt.-% for the manufacture of a conductive layer on a titanium strip.

Finally, the last embodiment of the invention relates to the use of a titanium strip provided with a coating of nickel of a vanadium content of 0 to 10 wt.-%, preferably approx. 1 to approx. 8 wt.-% and most preferably 7 wt.-% as a contact strip for electrolysis cells.

Preferentially such titanium strips are used that have a nickel or nickel-vanadium layer of a thickness of approx. 0.5 to approx. 10 μm, preferably approx. 1 to approx. 8 μm and most preferably approx. 1 to approx. 5 μm.

### EXAMPLES

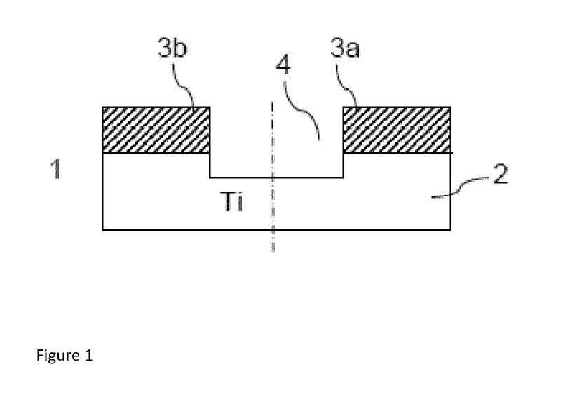

Additional features, details and advantages of the invention emerge from the following description and FIG. 1 showing a simplified sectional view of a contact strip according to the invention.

The contact strip generally designated as 1 is made up by a titanium strip 2, coated with a layer of nickel or a layer of nickel containing 7% vanadium by way of physical vapour deposition.

To allow that two contact webs 3a and 3b be formed, the centre part of especially the contact strip may have been removed mechanically, for example, such that a longitudinal groove 4 is obtained.

Below an example is described in more detail: A titanium strip coated with NiV7 in a PVD process was attached to the anode side of a cell element. A current of 16.3 kA was applied to the cell element. A voltage drop of 6 mV per kAm² could be measured. This value corresponds to contact strips that have been coated by explosion-bonding. Hence it could be demonstrated that this process serves to manufacture contact strips of high electric effectiveness.

Advantages involved in the present invention:
By using the PVD process it is possible to achieve high material utilisation, this process being thus less expensive than the explosion-bonding method.
The process allows coating larger contact surfaces and thereby further reducing voltage drops, which can be compared to explosion-bonding. Thus it is possible to further increase the electric effectiveness.

List of reference numbers and designations:

1 Contact strips

2 Titanium strip

3a, 3b Contact webs

4 Groove

1. Contact strip for electrolysis cells, the contact strip consisting of a titanium strip which has been coated with a layer of nickel containing 0 to 10 wt.-% vanadium by way of physical vapour deposition.

2. Contact strip according to claim 1, wherein the layer of nickel contains 7 wt.-% vanadium.

3. Contact strip according to claim 1, wherein the layer of nickel or nickel-vanadium has a thickness of approximately from 0.5 to approximately 10 μm.

4. Contact strip according to claim 1, wherein the layer of nickel or nickel-vanadium has a thickness of approximately from 1 to approximately 8 μm.

5. Contact strip according to claim 1, wherein the layer of nickel or nickel-vanadium has a thickness of approximately from 1 to approximately 5 μm.

6. Process for the manufacture of contact strips for electrolysis cells, comprising depositing a layer of nickel containing 0 to 10 wt.-% vanadium is deposited on a titanium strip by way of physical vapour deposition.

7. Process according to claim 6, wherein a layer of nickel containing 7 wt.-% vanadium is deposited.

8. Process according to claim 6, wherein the physical vapour deposition is carried out by
(a) loading a vacuum chamber with at least one titanium strip,
(b) closing and evacuating the vacuum chamber,
(c) cleaning the substrate by introducing a gaseous reducing agent into the vacuum chamber,
(d) subsequently removing the gaseous reducing agent,
(e) introducing the nickel or nickel-vanadium into the vacuum chamber and coating the titanium strip with an approximately from 0.5 to approximately 10 μm thick layer by vapour deposition, ion plating or cathode sputtering, and
(f) finally re-flooding the vacuum chamber and removing the coated substrate from the chamber.

9. Process according to claim 8, wherein the process steps (a) to (f) of physical vapour deposition are performed from one step to the next under vacuum at different pressures, which are set by means of an inert gas.

10. Process according to claim 6, wherein a vapour deposition method from the group of thermal deposition, electron beam deposition, laser beam deposition, arc deposition and molecular beam epitaxy is selected as a coating process.

11. A conductive layer on a titanium strip comprising nickel of a vanadium content of 0 to 10 wt.-%.

12. The conductive layer according to claim 11, wherein the nickel contains 7 wt. -% vanadium.

13.-15. (canceled)
